(19) United States
(12) Patent Application Publication
(10) Pub. No.: US 2025/0140769 A1
(43) Pub. Date: May 1, 2025

(54) INTEGRATED CIRCUIT PACKAGE WITH INTEGRATED HEAT SINK

(71) Applicant: TEXAS INSTRUMENTS INCORPORATED, Dallas, TX (US)

(72) Inventors: Yunyi Gong, Tokyo (JP); Kenji Otake, Nagano (JP); Hidetoshi Inoue, Oyama-shi (JP); Sombuddha Chakraborty, Redwood City, CA (US); Jonathan Montoya, Dallas, TX (US); Osvaldo Lopez, Annandale, NJ (US)

(21) Appl. No.: 18/498,092

(22) Filed: Oct. 31, 2023

(51) Int. Cl. H01L 25/18; H01L 21/48; H01L 21/56; H01L 23/00; H01L 23/29; H01L 23/31; H01L 23/373

(52) U.S. Cl. CPC H01L 25/18; H01L 21/4853; H01L 21/4871; H01L 21/565; H01L 23/293; H01L 23/3107; H01L 23/3736; H01L 24/32; H01L 2224/32245; H01L 2924/19011; H01L 2924/19042

(57) ABSTRACT

A packaged integrated circuit (IC) includes a package substrate and an IC on the package substrate. A first material is on the package substrate and encapsulates the IC. An inductor is coupled to the package substrate. A heat sink includes a second material. The heat sink is coupled to the IC. A third material is on the first material and encapsulates the inductor and at least part of the heat sink. The second material has a higher thermal conductivity than the first and third materials.

### BACKGROUND

An inductor can store energy in a magnetic field when electric current flows through the inductor and can provide an electric current by discharging the stored energy. Inductors can have many applications, such as proximity sensing, energy storage, actuation, power transmission, and filtering. An inductor may be coupled to an integrated circuit (IC), which can include circuits that operate with the inductor to support those and other applications. In some examples, the inductor and the corresponding circuits can be encapsulated in an integrated circuit package, which can reduce the footprint of the integrated circuit and shorten the interconnects between the inductor and the circuits to which it connects. The integrated circuit package, however, may affect the operations of the inductor and the integrated circuit.

### SUMMARY

In one example, a packaged integrated circuit (IC) includes a package substrate and an IC on the package substrate. A first material is on the package substrate and encapsulates the IC. An inductor is coupled to the package substrate. A heat sink includes a second material. The heat sink is coupled to the IC. A third material is on the first material and encapsulates the inductor and at least part of the heat sink. The second material has a higher thermal conductivity than the first and third materials.

In another example, a method includes encapsulating an IC attached to a package substrate with an insulation material and forming solder on first and second metal posts attached to the package substrate and surrounded by the insulation material. The method also includes attaching a heat sink to the IC, attaching an inductor to the solder on the first and second metal posts, and encapsulating the inductor and the heat sink with a magnetic material.

In yet another example, a heat sink includes a first portion and a second portion. The first portion includes a magnetic material. The first portion is attachable to a surface of an integrated circuit. The second portion includes the magnetic material and extends away from the first portion.

### BRIEF DESCRIPTION OF THE DRAWINGS

FIG. 1 is a schematic diagram of a packaged integrated circuit (IC) including an IC, an inductor, and a heat sink, in an example.

FIG. 2 is a schematic diagram of a cross-section of the packaged IC of FIG. 1, in an example.

FIG. 3 is a schematic illustrating an example magnetic material, in an example.

FIG. 4 is a schematic diagram of a packaged IC in which an IC and heat sink are laterally adjacent an inductor on a substrate, in an example.

FIG. 5 is a schematic diagram of a packaged IC including an IC, an inductor, and a heat sink, in another example.

FIG. 6 is a schematic diagram of a packaged IC including an IC, an inductor, and a heat sink a portion of which extends into the core region of the inductor, in yet another example.

FIG. 7 is a flowchart illustrating a method of fabricating a packaged IC, in an example.

FIGS. 7, 8, 9, 10, 11 and 12 are schematics illustrating fabrication operations of a packaged IC as part of the method of FIG. 7, in an example.

### DETAILED DESCRIPTION

The same reference numbers or other reference designators are used in the drawings to designate the same or similar (either by function and/or structure) features.

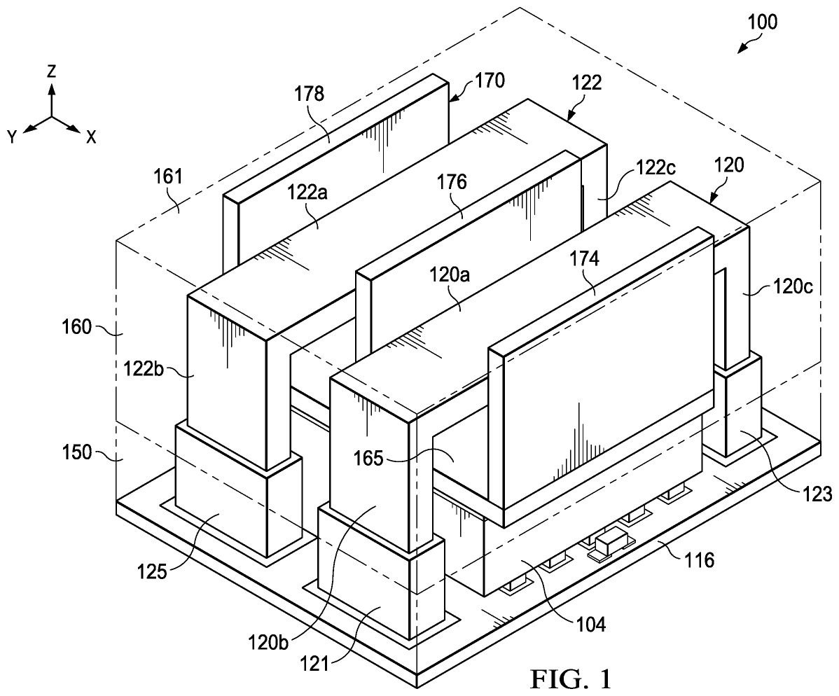

FIG. 1 is a schematic diagram of an example packaged integrated circuit (IC) 100 that includes an IC 104 on a package substrate 116. Metal interconnects (shown in other figures) can attach IC 104 to package substrate 116. Packaged IC 100 also includes a first material 150, a heat sink 170 which includes a second material, inductors 120 and 122, and a third material 160. Heat sink 170, described below, is attached to a surface of IC 100. The first material 150 encapsulates IC 104 and can surround the metal interconnects. In the example of FIG. 1, inductors 120 and 122 are over IC 104 and on the first material 150. Inductor 120 includes a coil portion 120a coupled to stilts 120b and 120c. Stilts 120b and 120c are coupled to package substrate 116 through metal posts (e.g., metal posts 121 and 123) at opposing sides of IC 104. Either or both of the stilts 120b and 120c of inductor 120 can be coupled to one or more interconnects of the IC 104 through the package substrate 116. Similarly, inductor 122 includes a coil portion 122a coupled to stilts 122b and 122c. Stilts 122b and 122c also are coupled to package substrate 116 at opposing sides of IC 104 through metal posts, e.g., metal post 125 (the opposing metal post is hidden from view in FIG. 1). Each inductor 120 and 122 includes a coil region 165. The inductors are arranged such that their core regions 165 are generally in alignment with each other. Other components may be included within the packaged IC 100 as well. The IC 104 and inductors 120 and 122 can be part of any of numerous devices such as power converters (e.g., buck converters, boost converters, etc.), filters, etc. Two inductors 120 and 122 are shown in the example of FIG. 1 but one inductor or three or more inductors may be included as part of packaged IC 100 in other examples.

The third material 160 is on the first material 150 and encapsulates the inductors 120 and 122. In one example, the third material 160 is the same as the first material 150. In examples in which the first and third materials are the same, the first and third materials may be a magnetic material which helps to concentrate the magnetic fields generated by inductors 120 and 122 to improve the efficiency of the inductors.

In other examples, the first material 150 is different from the third material 160. For example, the first material can be an insulation material (e.g., an epoxy molding compound (EMC)) to reduce the risk of leakage current between the metal interconnects of IC 104. The EMC may include non-electrically conductive particles, such as dielectric particles (e.g., silicon dioxide particles, silica particles, alumina particles, etc.) suspended in a resin. The third material can be a magnetic material, such as a magnetic molding compound (MMC) with metallic particles suspended in an epoxy/resin, to concentrate the magnetic fields generated by the inductors. In a case where the first material 150 is an insulation material, the first material 150 can have poor thermal conductivity and do not facilitate conduction of heat generated by IC 104 away from IC 104. Having heat sink 170 integrated in packaged IC 100 and directly contacting IC 104 (or proximate IC 104) allow more effective removal of heat from IC 104, which can prevent overheating and improve the operation of IC 104.

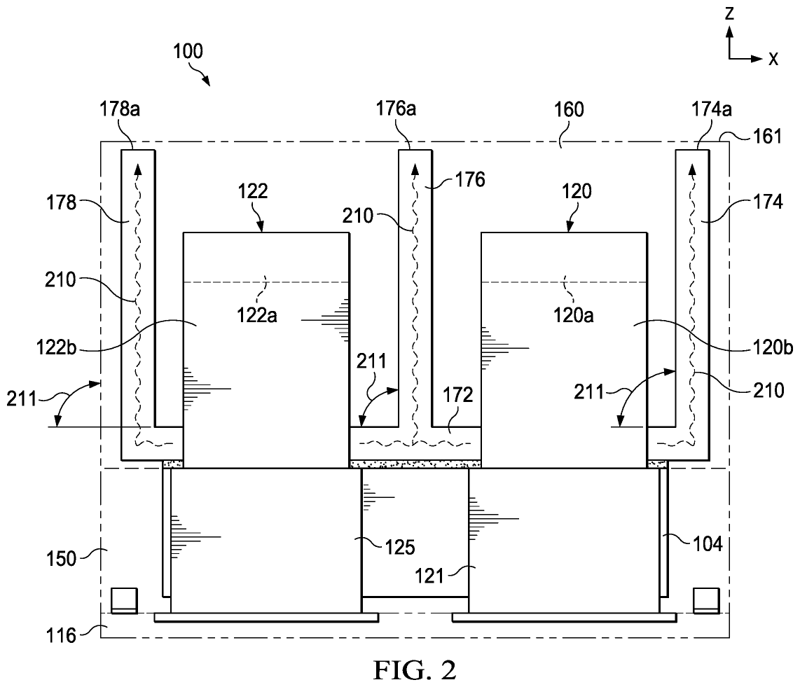

FIG. 2 is a cross-sectional view of packaged IC 100. Referring to FIGS. 1 and 2, heat sink 170 includes a portion 172 and additional portions 174, 176, and 178. In this example, portion 172 of heat sink 170 extends within the core region 165 of inductors 120 and 122. Portions 174, 176 and 178 protrudes from portion 172. In the examples of FIGS. 1 and 2, portions 174, 176, and 178 are substantially orthogonal (e.g., approximately 90 degrees) to portion 172. Accordingly, each of portions 174, 176, and 178 extend away from portion 172 and IC 104 at an angle 211 (FIG. 2) of approximately 90 degrees. FIG. 2 shows an example in which the tops 174a, 176a, and 178 of portions 174, 176, and 178 of heat sink 170 are covered by the third material 160.

Heat sink 170 can be constructed of a material with a sufficiently high thermal conductivity to adequately remove heat from IC 104 in the direction of arrows 210. Heat is removed from IC 104 in a direction from IC 104 towards the top surface 161 of third material 160. FIG. 2 shows an example in which the tops 174a, 176a, and 178 of portions 174, 176, and 178 of heat sink 170 are covered by the third material 160, but sufficiently close to surface 161 to be able to allow heat to be removed from the packaged IC 100. In another example, the tops 174a, 176a, and 178a are exposed through surface 161. Additional heat may be removed from IC 104 downwards through substrate 116.

In an example, heat sink 170 includes a metal, e.g., copper. All of portions 172, 174, 176, and 178 may be constructed of a same metal such as copper. In another example, heat sink 170 includes a magnetic material that has a relatively high magnetic permeability and a relatively high thermal conductivity. Having a relatively high magnetic permeability helps to concentrate the magnetic flux created by current flowing through inductors 120 and 122 in the core region 165 while the relatively high thermal conductivity property helps to remove heat from IC 104.

In examples in which a portion of heat sink 170 includes a magnetic material, such a magnetic material can be free of resin. Further, the magnetic material can include metal particles each coated with an insulation layer, such as silicon dioxide (SiO₂). The metal particles of heat sink 170 can include iron particles, aluminum particles, or chromium particles.

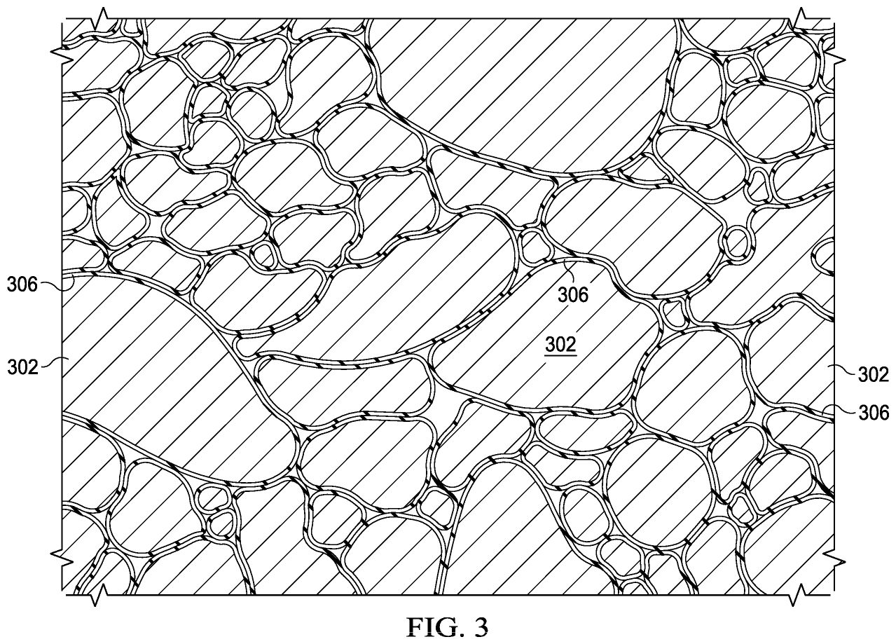

FIG. 3 is a schematic illustrating an example magnetic material which can be part of heat sink 170. The magnetic material can include particles 302, such as iron particles, aluminum particles, or chromium particles. Each particle can be coated with an insulation layer 306, such as SiO₂. The coated particles can be compressed together (e.g., by a sintering process) to provide structural strength and rigidity. Because of the compression, the particles do not need to be suspended in a resin to provide the strength and rigidity, therefore the material is free of resin. Because of the absence of the resin, the thermal conductivity can be improved. Also, the metallic particles can be magnetized, which provides a relatively high magnetic permeability. Accordingly, portions 172, 174, 176, and 178 of heat sink 170 formed using the magnetic material illustrated in FIG. 3 can provide high thermal conductivity to remove heat from 104, while the portion 172 can also provide high magnetic permeability to concentrate the magnetic flux in core region 165.

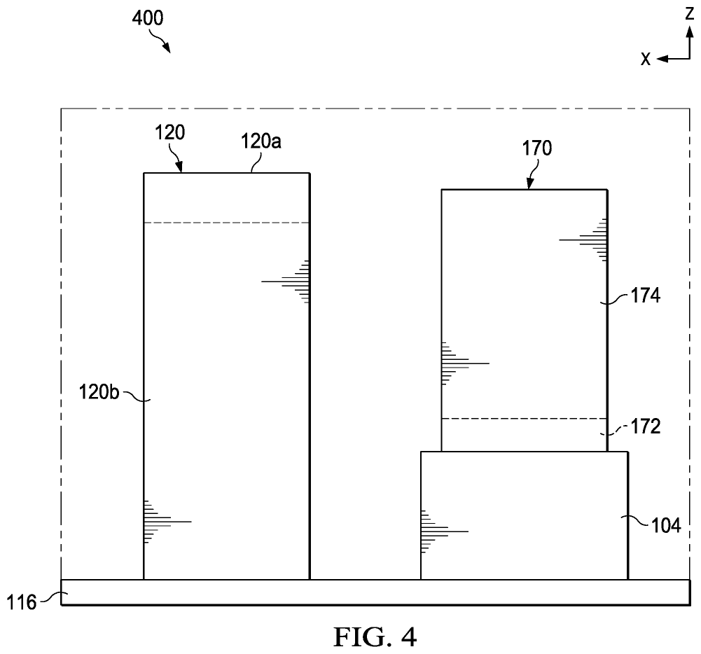

FIG. 4 shows an example of a packaged IC 400 in which IC 104 and inductor 120 are attached to the package substrate 116 such that IC 104 and inductor 120 are laterally adjacent one another on package substrate 116. In this example, packaged IC 400 may have only one inductor, e.g., only one of inductors 120, 122. Heat sink 170 is attached to IC 104 and helps to remove heat from IC 104. Heat sink 170 is laterally adjacent inductor 120 in the example of FIG. 4. Accordingly, because heat sink 170 is not within the core region 165 of inductor 120, heat sink 170 need not have, but can have, a relatively high magnetic permeability. Heat sink 170 has a sufficiently high thermal conductivity to remove heat from IC 102. Accordingly, heat sink 170 in this example can be made of a thermally conductive metal such as copper.

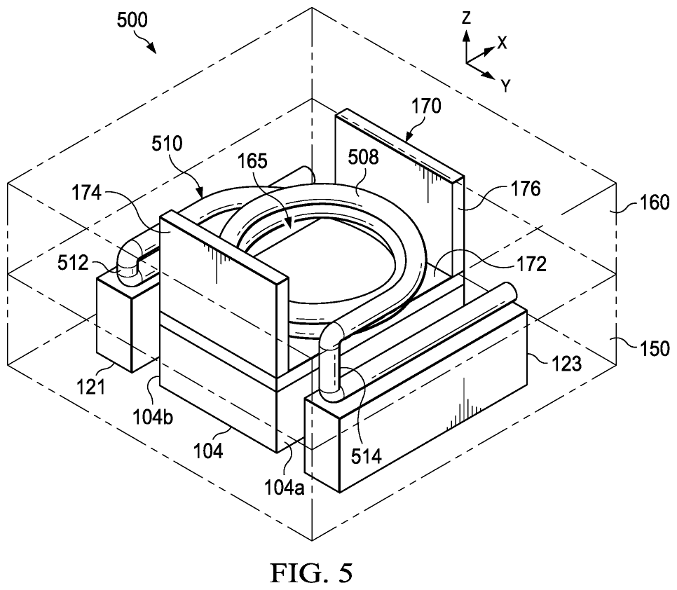

FIG. 5 is a schematic diagram of an example packaged integrated circuit (IC) 100 that includes IC 104 on the package substrate (not shown in this figure). As described above, packaged IC 500 includes a first material 150 (e.g., an insulation material) that encapsulates IC 104. In the example of FIG. 5, an inductor 510 is over IC 104 and on the insulation material 150. Inductor 510 includes a coil portion 508 coupled to stilts 512 and 514. Coil portion 508 has a core region 165. Stilts 512 and 514 are coupled to the package substrate at opposing sides 104a and 104b of the IC 104. Either or both of the stilts 512 and 514 of inductor 510 can be coupled to one or more interconnects of IC 104 through the package substrate. Other components may be included within the packaged IC 500 as well. A third material 160 (e.g., a material material) is on the first material 150 and encapsulates the inductor 110. As described above, the third material 160 can help to concentrate the magnetic field generated by inductor 510 to improve the inductor's efficiency.

In the example of FIG. 5, packaged IC 500 includes heat sink 170 having a portion 172 and orthogonal portions 174 and 176. Heat sink 170 can be constructed of metal, e.g., copper, as described above. Because heat sink 170 does not have a portion that extends through the inductor's core region 165, heat sink 170 need not have a relatively high magnetic permeability to help concentrate the inductor's magnetic field.

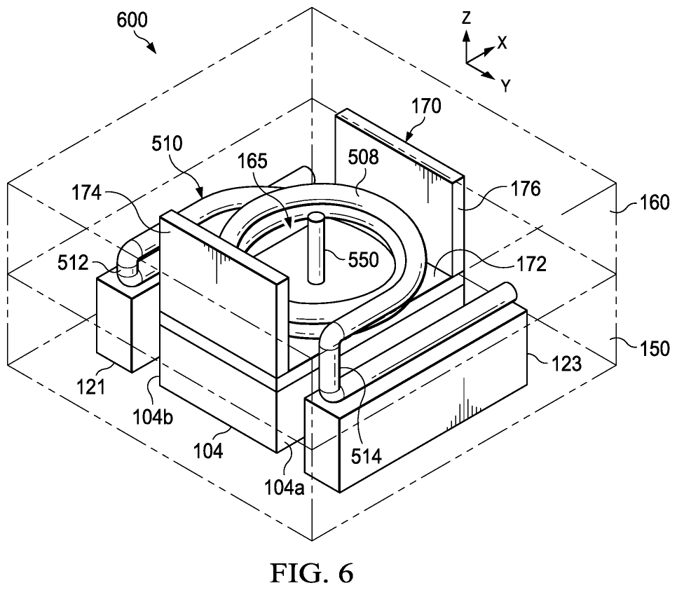

FIG. 6 is a schematic diagram of a packaged IC 600 similar to that of packaged IC 500. The heat sink 170 of packaged IC 600 includes a post 550 that extends through the core region 165 of inductor 508. In this example, post 550 can include a magnetic material, such as that described above. Heat sink portions 172, 174, and 176 do not extend through core region 165 and thus need not include, but can include, a magnetic material. For example, heat sink portions 172, 174, and 176 may include a metal, e.g., copper, and post 550 can include a magnetic material, such as the magnetic material shown in FIG. 3. All of heat sink portions 172, 174, and 176 and post 550 include a material with a relatively high thermal conductivity.

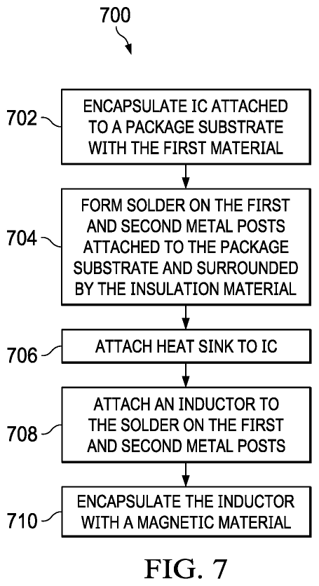

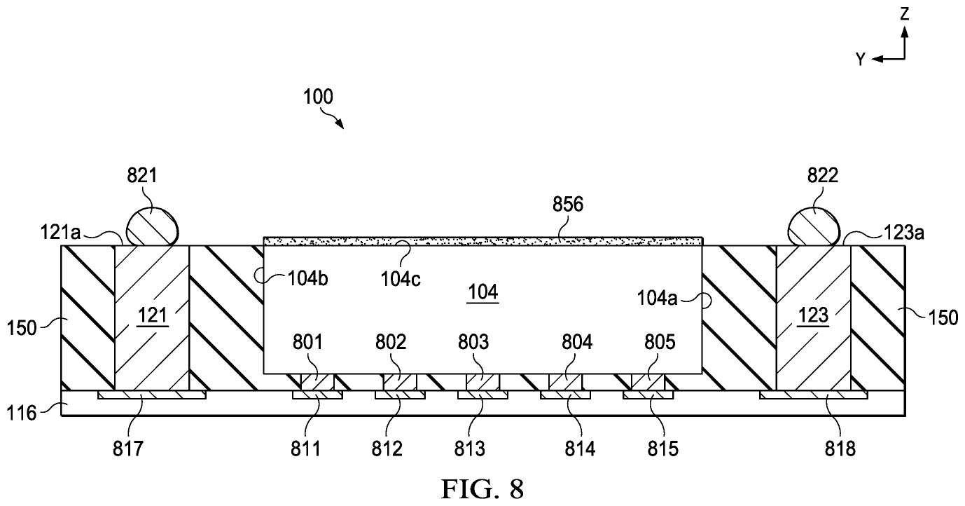

FIG. 7 is a flowchart of an example method 700 for fabricating at least a portion of the packaged IC 100, and FIGS. 8-13 are schematics illustrating cross-sections of portions of the packaged IC 100 during various stages of fabrication. The same or similar fabrication steps can be performed to fabricate packaged ICs 400, 500, and 600 as well.

Referring to FIGS. 7 and 8, in operation 702 IC 104 is attached to package substrate 116 and can be encapsulated with the first material 150 (e.g., insulation material). Metal posts 121 and 122 are also attached to the package substrate 116 and are surrounded by the first material 150. FIG. 7 illustrates metal interconnects 801, 802, 803, 804, and 805 of IC 104 attached to corresponding metal pads 811, 812, 813, 814, and 815 of package substrate 116. Although five pairs of interconnects and pads are shown, packaged IC 100 can include any number of pairs of interconnects and pads. In an example, IC 104 may be a semiconductor die which may previously have been fabricated through wafer-level processing (e.g., multiple semiconductor dies fabricated on a single wafer and then singulated into the individual dies). Metal posts 121 and 122 are coupled to package substrate 116 by way of the respective metal pads 817 and 818. Metal posts 121 and 122 can be surrounded by the first material 150. The insulation material 150 also encapsulates IC 104 and can also encapsulate package substrate 116.

An example process for encapsulating IC 104 can include attaching IC 104 to package substrate 116 by reflowing solder between the metal interconnects 801-805 and the corresponding metal pads 811-815. Further, metal posts 121 and 122 can be formed on the package substrate 116 by electroplating, or by other techniques (e.g., by soldering the metal posts onto package substrate 116). For example, a seed layer can be formed on metal pads 817 and 818. The seed layer can include a copper species. The copper can then be electroplated on metal pads 817 and 818.

Further, the first material 150 can be deposited on package substrate 116 to cover metal posts 121 and 122, IC 104, and the interconnects between IC 104 and package substrate 116. In some examples, the device assembly of FIG. 8 can be disposed in a mold chase (e.g., by a nozzle), and the first material 150 in molten/liquid form can be deposited into the mold chase to cover package substrate 116, metal posts 121 and 122, IC 104, and the interconnects. The first material 150 can then be cured to become in solid form and encapsulate metal posts 121 and 122, IC 104, and the interconnects between IC 104 and package substrate 116.

A grind process can be performed to some of the first material 150 to expose top surfaces 121a and 122a of, respectively, metal posts 121 and 122 as well as the top surface 104c of IC 104. The grind process can be a mechanical grind process.

Referring still to FIGS. 7 and 8, in operation 704, solder (e.g., solder 821 and 822 of FIG. 8) are formed on the exposed top surfaces 121a and 122a of the respective metal posts 121 and 122. Further, an adhesive layer 856 is formed on the exposed surface 104c of IC 104. Adhesive layer 856 can be a thermally adhesive layer by which heat sink 170 can be attached to IC 104.

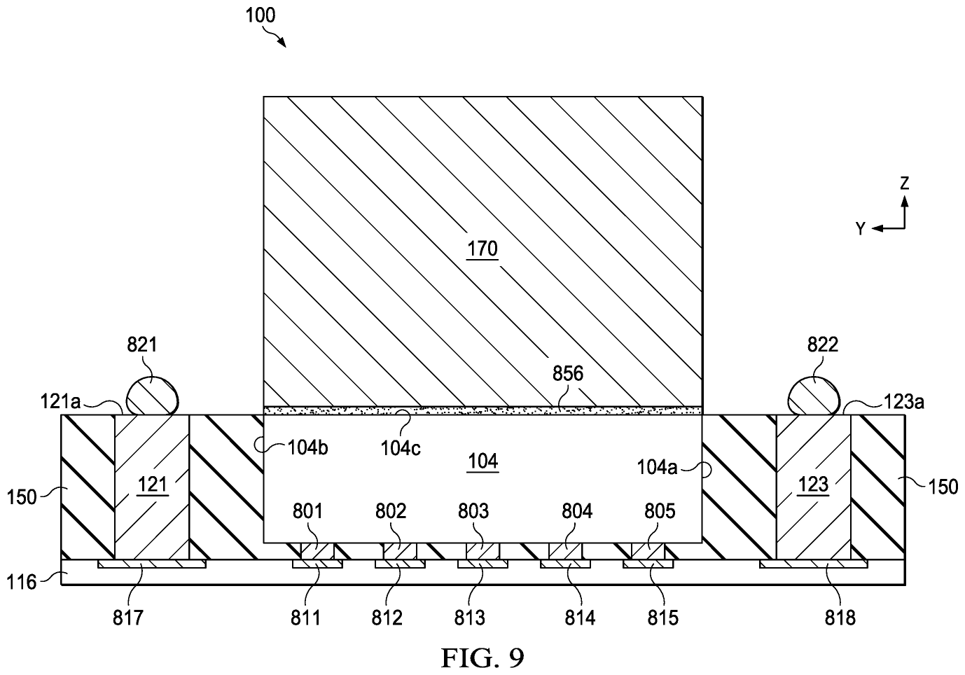

Referring to FIGS. 7 and 9, in operation 706, heat sink 170 is attached to IC 104. In one example, heat sink is placed on adhesive layer 856 by, for example, a pick-and-place process.

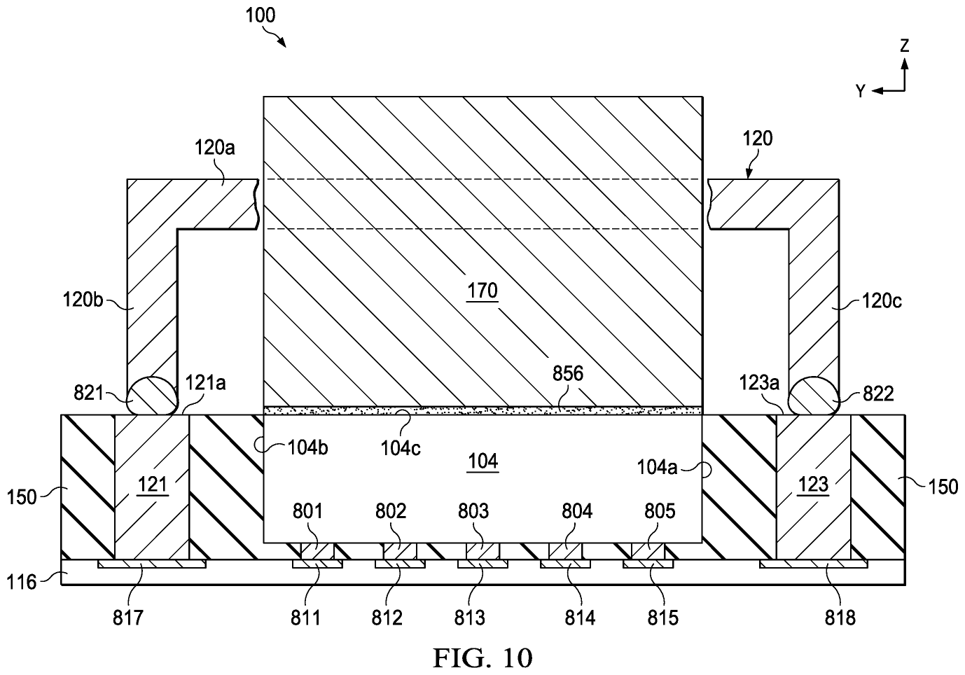

In operation 708 of FIG. 7 and with reference to FIG. 10, an inductor is attached to metal posts, e.g., metal posts 121 and 122. The inductor may be either or both of inductors 120 and 122. The inductor may be attached to posts 121 and 122 by, for example, a pick-and-process and solder 821 and 822 can be heated to reflow the solder.

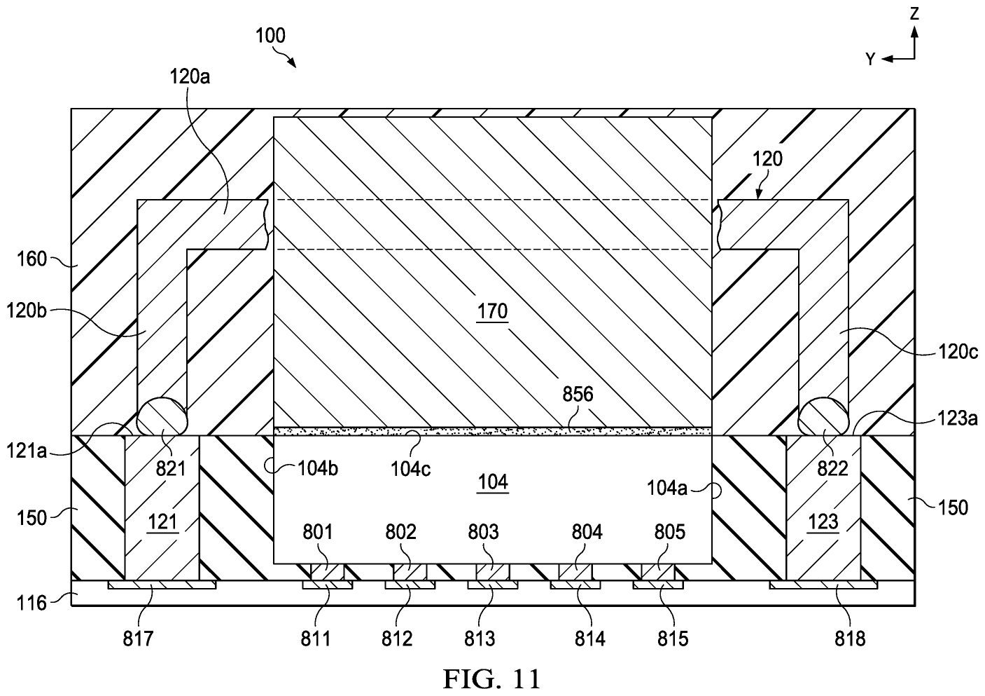

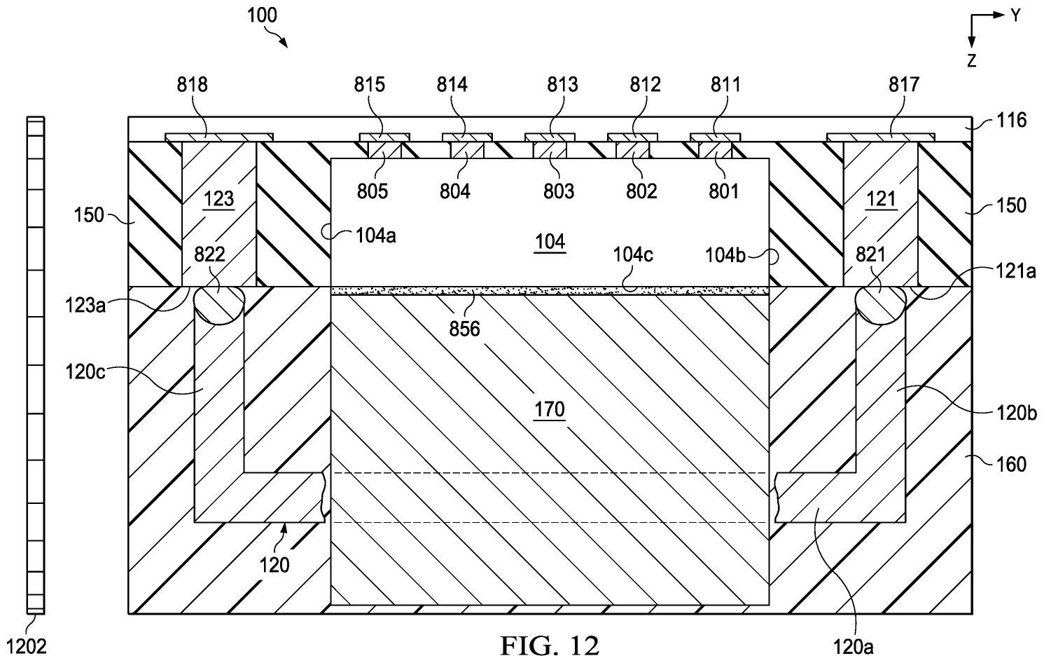

Also, referring to FIG. 7 and FIG. 11, the inductor can be encapsulated with the third (e.g., magnetic) material 160, as described above. In some examples, the device assembly of FIG. 10 including inductor 120 and first material 150 can be disposed in a mold chase, and the third material 160 in molten/liquid form can be deposited into the mold chase to cover inductor 120 and the first material 150. The third material 160 can then be cured to become in solid form and encapsulate inductor 120. Referring to FIG. 12, after the third material 160 is solidified, part of the third material 160 can removed by dicing with a saw 1202.

The operations described in FIGS. 6-16 can be performed as part of a packaging process on a semiconductor die after the die is singulated from a wafer. Accordingly, the encapsulation of the semiconductor die in the insulation material 150 needs not be performed in wafer-level processing operation, which can reduce the overall cost and complexity of the fabrication operation of IC 100.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

Uses of the phrase “ground voltage potential” and/or “ground” in this description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter, or, if the value is zero, a reasonable range of values around zero.

Modifications are possible in the described examples, and other examples are possible, within the scope of the claims.

What is claimed is:

1. A packaged integrated circuit (IC) comprising:
a package substrate;
an integrated circuit (IC) on the package substrate;
a first material on the package substrate and encapsulating the IC;
an inductor coupled to the package substrate;
a heat sink including a second material, the heat sink coupled to the IC; and
a third material on the first material and encapsulating the inductor and at least part of the heat sink, in which the second material has a higher thermal conductivity than the first and third materials.

2. The packaged IC of claim 1, wherein the second material is free of resin.

3. The packaged IC of claim 1, wherein the second material includes metal particles each coated with an insulation layer.

4. The packaged IC of claim 3, wherein the metal particles include at least one of: iron particles, aluminum particles, or chromium particles.

5. The packaged IC of claim 1, wherein the second material includes Copper.

6. The packaged IC of claim 1, wherein the heat sink includes a first portion attached to the IC and a second portion that protrudes from the first portion.

7. The packaged IC of claim 6, wherein the inductor includes a coil surrounding a core region, and the first portion extends within the core region.

8. The packaged IC of claim 7, wherein the second material includes a magnetic material.

9. The packaged IC of claim 6, wherein the inductor includes a coil surrounding a core region extending away from the IC, and the second portion extends within the core region.

10. The packaged IC of claim 6, wherein the first portion and second portion include the second material.

11. The packaged IC of claim 6, wherein the second portion includes a fourth material different from the second material, the fourth material having a higher thermal conductivity than each of the first and third materials.

12. The packaged IC of claim 11, wherein the fourth material includes Copper.

13. The packaged IC of claim 1, wherein the heat sink is laterally adjacent to the inductor.

14. The packaged IC of claim 1, wherein the first and third materials are the same material.

15. The packaged IC of claim 1, wherein the first and third materials are different materials.

16. The packaged IC of claim 1, wherein the first material is an insulation material, and the third material is a magnetic material.

17. The packaged IC of claim 16, wherein the insulation material includes non-electrically conductive particles and a first epoxy resin in which the non-electrically conductive particles are suspended, and the magnetic material includes metal particles and a second epoxy resin in which the metal particles are suspended.

18. The packaged IC of claim 1, wherein the inductor is a first inductor, and the packaged IC comprises a second inductor coupled to the package substrate, and the third material encapsulates the second inductor.

19. The packaged IC of claim 18, wherein the heat sink includes a first portion attached to the IC, a second portion orthogonal to the first portion and extending away from the IC and between the first and second inductors, and a third portion orthogonal to the first portion.

20. The packaged IC of claim 19, wherein the first portion of the heat sink has a higher magnetic permeability than the first material.

21. A method comprising:
encapsulating an integrated circuit (IC) attached to a package substrate with an insulation material;
forming solder on first and second metal posts attached to the package substrate and surrounded by the insulation material;
attaching a heat sink to the IC;
attaching an inductor to the solder on the first and second metal posts; and
encapsulating the inductor and the heat sink with a magnetic material.

22. The method of claim 21, wherein the inductor includes a coil portion, and the heat sink includes a first portion and a second portion, and wherein:
attaching the heat sink to the IC includes attaching the first portion to the IC; and
attaching the inductor to the solder on the first and second metal posts includes placing the coil portion over the first portion.

23. The method of claim 21, wherein the heat sink includes a material having a higher magnetic permeability than the insulation material.

24. A heat sink comprising:
a first portion including a magnetic material, the first portion attachable to a surface of an integrated circuit; and
a second portion including the magnetic material and protruding away from the first portion.

25. The heat sink of claim 24, wherein the magnetic material is free of resin.
